(19) United States
(12) Patent Application Publication
(10) Pub. No.: US 2014/0049165 A1
(43) Pub. Date: Feb. 20, 2014

(54) SEMICONDUCTOR LIGHT EMITTING DEVICE AND LIGHTING APPARATUS

(71) Applicant: KABUSHIKI KAISHA TOSHIBA, Tokyo (JP)

(72) Inventors: Hisashi SOGABE, Fukuoka-ken (JP); Takanobu KAMAKURA, Fukuoka-ken (JP); Tetsuya MURANAKA, Fukuoka-ken (JP); Koichi MATSUSHITA, Fukuoka-ken (JP); Hitoshi KAWASAKI, Aichi-ken (JP); Toshio SHIOTANI, Fukuoka-ken (JP)

(21) Appl. No.: 13/781,636

(22) Filed: Feb. 28, 2013

(30) Foreign Application Priority Data
Aug. 20, 2012 (JP) 2012-181902

(51) Int. Cl. H01L 33/62; H05B 33/08; H01L 33/08

(52) U.S. Cl. CPC H01L 33/62; H01L 33/08; H05B 33/0854
USPC 315/151; 257/88

(57) ABSTRACT

A semiconductor light emitting device includes a substrate, a first semiconductor light emitting element and a second semiconductor light emitting element. A first semiconductor light emitting element is provided on the substrate and includes a first layer having a first conductivity type, a first light emitting layer, and a second layer having a second conductivity type. A second semiconductor light emitting element is provided on the substrate and includes a third layer having a second conductivity type, a second light emitting layer, and a fourth layer having a first conductivity type. The first layer and the third layer are electrically connected. A peak emission wavelength of light emitted from the first light emitting layer and a peak emission wavelength of light emitted from the second light emitting layer are substantially same.

### CROSS-REFERENCE TO RELATED APPLICATIONS

This application is based upon and claims the benefit of priority from the prior Japanese Patent Application No. 2012-181902, filed on Aug. 20, 2012; the entire contents of which are incorporated herein by reference.

### FIELD

Embodiments described herein relate generally to a semiconductor light emitting device and a lighting apparatus.

### BACKGROUND

Semiconductor light emitting devices used for lighting apparatus and marker lamps of automobiles are required to be small in size and emit light having a high light flux.

If the semiconductor light emitting device can have a configuration in which a plurality of semiconductor light emitting elements are freely connected in series or in parallel, it becomes easy to obtain a high light flux while reducing the size.

If a stacked body provided on one substrate and including a light emitting layer is divided, light emitting elements can be connected in parallel. However, it is difficult to increase the operating voltage, and a circuit that reduces the power supply voltage down to the operating voltage of the semiconductor light emitting device is needed.

On the other hand, if divided light emitting elements are connected in series on one substrate to bring the operating voltage close to the power supply voltage, the electrode structure becomes complicated, and the size is increased.

### BRIEF DESCRIPTION OF THE DRAWINGS

FIG. 1A is a schematic plan view of a semiconductor light emitting device according to a first embodiment, FIG. 1B is a schematic cross-sectional view taken along line A-A, and FIG. 1C is a wiring diagram;

FIGS. 2A to 2D are schematic views describing a method for manufacturing a semiconductor light emitting device according to the first embodiment;

FIG. 3 is a schematic cross-sectional view of a wafer state of the semiconductor light emitting device in which the first and second electrodes are provided;

FIG. 4A is a schematic plan view of a semiconductor light emitting device according to a second embodiment, FIG. 4B is a schematic cross-sectional view taken along line A-A, and FIG. 4C is a wiring diagram;

FIG. 5A is a schematic cross-sectional view of a modification example of the second embodiment, and FIG. 5B is a wiring diagram;

FIG. 6A is a configuration diagram of a lighting apparatus according to a third embodiment, and FIG. 6B is a block diagram showing an abnormality detection circuit for illumination light;

FIG. 7 is a timing chart describing the operation of abnormality detection;

FIG. 8A is a schematic cross-sectional view of a semiconductor light emitting device according to a fourth embodiment, and FIG. 8B is a schematic cross-sectional view taken along line B-B;

FIG. 9A is a schematic plan view of a first configuration, FIG. 9B is a wiring diagram thereof, FIG. 9C is a schematic plan view of a second configuration, FIG. 9D is a wiring diagram thereof, FIG. 9E is a schematic plan view of a third configuration, and FIG. 9F is a wiring diagram thereof;

FIG. 10A is a schematic plan view of a semiconductor light emitting device according to a modification example of the fourth embodiment, and FIG. 10B is a schematic cross-sectional view taken along line C-C; and

FIG. 11A is a schematic plan view of a first configuration of a semiconductor light emitting device according to a fifth embodiment, FIG. 11B is a wiring diagram thereof, FIG. 11C is a schematic plan view of a second configuration, FIG. 11D is a wiring diagram thereof, FIG. 11E is a schematic plan view of a third configuration, and FIG. 11F is a wiring diagram thereof.

### DETAILED DESCRIPTION

In general, according to one embodiment, a semiconductor light emitting device includes a substrate, a first semiconductor light emitting element and a second semiconductor light emitting element. A first semiconductor light emitting element is provided on the substrate and includes a first layer having a first conductivity type, a first light emitting layer provided on the first layer, and a second layer provided on the first light emitting layer and having a second conductivity type. A second semiconductor light emitting element is provided on the substrate and includes a third layer having a second conductivity type, a second light emitting layer provided on the third layer, and a fourth layer provided on the second light emitting layer and having a first conductivity type. The first layer and the third layer are electrically connected. A peak emission wavelength of light emitted from the first light emitting layer and a peak emission wavelength of light emitted from the second light emitting layer are substantially same.

Embodiments of the invention will now be described with reference to the drawings.

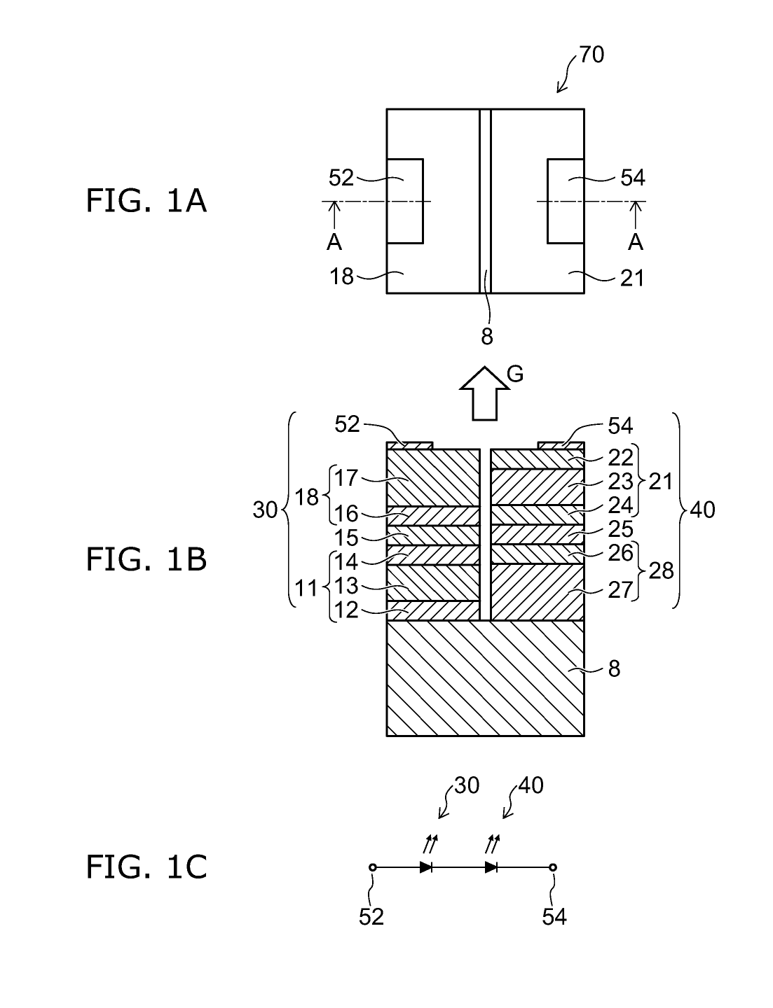

FIG. 1A is a schematic plan view of a semiconductor light emitting device according to a first embodiment, FIG. 1B is a schematic cross-sectional view taken along line A-A, and FIG. 1C is a wiring diagram.

A semiconductor light emitting device 70 has, as shown in FIG. 1C, a series connection configuration in which a first light emitting element 30 and a second light emitting element 40 are connected to a conductive substrate 8.

The conductive semiconductor substrate 8 is made of, for example, Si, GaAs, or the like, and is configured to have a high impurity concentration. The first semiconductor light emitting element 30 includes a first layer 11 having a first conductivity type, a light emitting layer 15, a second layer 18 having a second conductivity type, and a first electrode 52 in this order from the side of the conductive semiconductor substrate 8. The second semiconductor light emitting element 40 includes a third layer 28 having the second conductivity type, a light emitting layer 25, a fourth layer 21 having the first conductivity type, and a second electrode 54 in this order from the side of the conductive semiconductor substrate 8.

Although it is assumed that the conductive semiconductor substrate 8 is made of an n⁺-type Si in FIG. 1, the invention is not limited thereto. The conductive semiconductor substrate 8, the first layer 11, and the third layer 28 are configured to have a high impurity concentration. Therefore, a low contact resistance can be obtained while ohmic contact is kept between the conductive semiconductor substrate and the first layer 11 and between the conductive semiconductor substrate 8 and the third layer 28.

The first semiconductor light emitting element 30 and the second semiconductor light emitting element 40 may have substantially the same material, substantially the same impurity concentration, and substantially the same size within controllable bounds in manufacturing processes. Thus, the electrical characteristics and the optical characteristics can be made substantially the same.

In this specification, “the peak emission wavelength of emitted light is substantially the same” means that “the difference in the peak emission wavelength is 30 nm or less.” When a crystal growth process such as the MOCVD (metal organic chemical vapor deposition) method is used, the difference in the peak emission wavelength can be controlled to 30 nm or less. The “peak emission wavelength” refers to a wavelength at which the light emission intensity is at a maximum.

When the light emitting layers 15 and 25 are made of Inₓ(Ga_{1-y}Al_{y})₁₋ₓP (0≦x≦1, 0≦y≦0.6), the peak emission wavelength allows, for example, red light (a wavelength range of 610 to 700 nm) to be emitted upward or sideward. The red light can be used for, for example, marker lamps of automobiles, such as stop lamps, and the like. As the power source of on-vehicle lighting apparatus, a voltage near 12.5 V is used. The light emitting device of the first embodiment including two semiconductor light emitting elements connected in series has an operating voltage suitable for drive at near 12.5 V. Therefore, a high light flux can be obtained while the light emitting device is kept small in size.

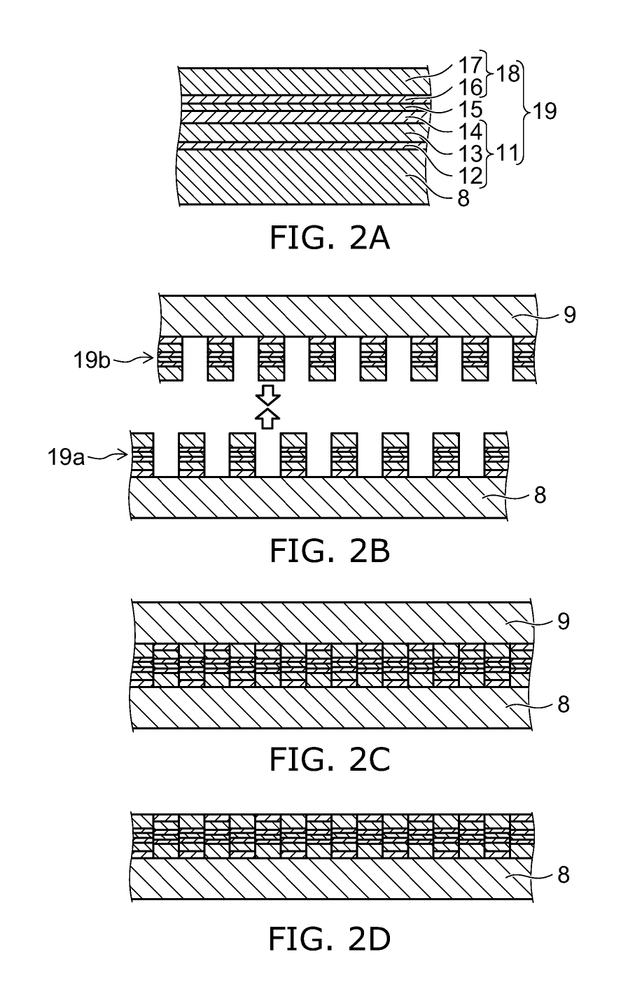

FIGS. 2A to 2D are schematic views describing a method for manufacturing a semiconductor light emitting device according to the first embodiment.

As shown in FIG. 2A, on the conductive semiconductor substrate 8, the first layer 11 having the first conductivity type and including a buffer layer 12, the light emitting layer 15, and the second layer 18 having the second conductivity type are provided in this order to form a stacked body 19 that constitutes the first semiconductor light emitting element 30. The first layer 11 may include a current spreading layer 13, a cladding layer 14, etc. from the buffer layer 12 side. The first layer 11 may include an undoped layer partly. The second layer 18 may include a cladding layer 16, a current spreading layer 17, a contact layer, etc. from the light emitting layer 15 side. The second layer 18 may further include an undoped layer formed of a superlattice layer or the like.

When the stacked body 19 is made of Inₓ(Ga_{1-y}Al_{y})₁₋ₓP (0≦x≦1, 0≦y≦1), each layer may be configured as follows, for example. The current spreading layer 13 is made of n-type In_{0.5}(Ga_{0.3}Al_{0.7})_{0.5}P, and is configured to have an impurity concentration of 1.6×10¹⁸ cm⁻³ and a thickness of 1.5 μm or the like. The cladding layer 14 is made of n-type In_{0.5}Al_{0.5}P, and is configured to have an impurity concentration of 4×10¹⁷ cm⁻³ and a thickness of 0.6 μm or the like.

The light emitting layer 15 is configured to have an MQW (multi-quantum well) structure that includes a well layer made of In_{0.5}Ga_{0.5}P and having a thickness of 4 nm and a barrier layer made of In_{0.5}(Ga_{0.4}Al_{0.6})_{0.5}P and having a thickness of 7 nm.

The cladding layer 16 is made of p-type In_{0.5}Al_{0.5}P, and is configured to have an impurity concentration of 4×10¹⁷ cm⁻³ and a thickness of 0.6 μm or the like. The current spreading layer 17 is made of p-type In_{0.5}(Ga_{0.3}Al_{0.7})_{0.5}P, and is configured to have an impurity concentration of 1.5×10¹⁸ cm⁻³ and a thickness of 1.5 μm or the like.

As shown in FIG. 2B, regions other than the regions where first semiconductor light emitting elements 30 are left are removed using the RIE (reactive ion etching) method or the like to form stacked bodies 19a. On the other hand, structures each of which is identical to the stacked body 19a are formed on a conductive semiconductor substrate 9, and regions other than the regions where second semiconductor light emitting elements 40 are left are removed using the RIE method or the like to form stacked bodies 19b. The two conductive semiconductor substrates 8 and 9 are superposed such that the separate convex-shaped stacked bodies 19a and 19b are opposed to each other in a staggered configuration, and wafer bonding using pressurization, heating, etc. is performed. Consequently, the structure of FIG. 2C is obtained. Further, the conductive semiconductor substrate 9 is removed. Thus, as shown in FIG. 2D, the stacked bodies 19a and 19b in which layers are stacked in directions opposite to each other are alternately aligned on the conductive semiconductor substrate 8. In the case where the conductive semiconductor substrate 8 is left as a support body, for example, wafer bonding may be performed by providing a metal thin layer on the exposed surface side of the substrate or on the surface side of the stacked body 19b.

The substrate for the crystal growth of the stacked bodies 19a and 19b may be made of, for example, GaAs, Si, or the like having electrical conductivity, and may be left as it is as a conductive substrate. Alternatively, it is also possible to use a substrate made of GaAs or the like as a crystal growth substrate, perform wafer bonding to a conductive Si substrate or a conductive GaP substrate, and remove the crystal growth substrate.

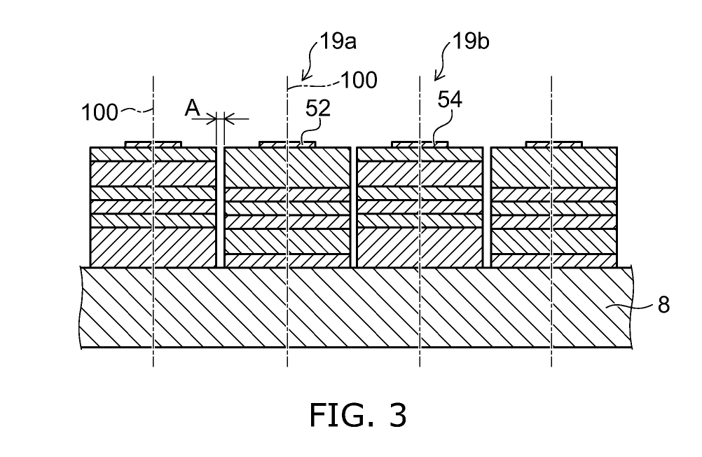

FIG. 3 is a schematic cross-sectional view of a wafer state of the semiconductor light emitting device in which the first and second electrodes are provided.

Although the n type is taken as the first conductivity type and the p type is taken as the second conductivity type, the conductivity types may be the opposite polarities. Positions including the center of the stacked body 19a forming the first semiconductor light emitting element 30 and the center of the stacked body 19b forming the second semiconductor light emitting element 40 are taken as dicing positions 100, and the workpiece is separated into chips. The stacked body 19a and the stacked body 19b may be, in a plan view, alternately disposed in a striped configuration. Alternatively, the stacked body 19a and the stacked body 19b may be two-dimensionally disposed in a lattice configuration in a plan view. Thus, the semiconductor light emitting device 70 of the first embodiment shown in FIG. 1 is completed. The longitudinal and lateral lengths of the chip may be, for example, in a range of 0.3 to 2 mm.

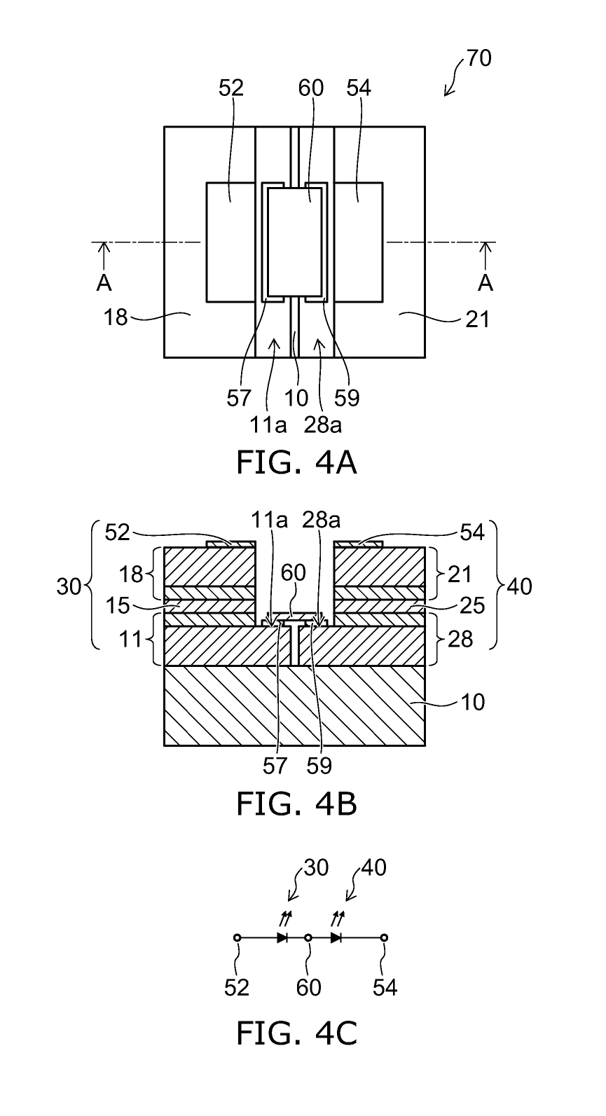

FIG. 4A is a schematic plan view of a semiconductor light emitting device according to a second embodiment, FIG. 4B is a schematic cross-sectional view taken along line A-A, and FIG. 4C is a wiring diagram.

The semiconductor light emitting device 70 has, as shown in FIG. 4C, a series connection configuration in which the first light emitting element 30 and the second light emitting element 40 are connected via an interconnection portion 60.

A substrate 10 may be, for example, sapphire having insulating properties or the like. The first semiconductor light emitting element 30 includes the first layer 11 having the first conductivity type, the light emitting layer 15, the second layer 18 having the second conductivity type, and the first electrode 52 in this order from the substrate 10 side. The second semiconductor light emitting element 40 includes the third layer 28 having the second conductivity type, the light emitting layer 25, the fourth layer 21 having the first conductivity type, and the second electrode 54 in this order from the insulative substrate 10 side.

A first exposed surface 11a provided on at least part of the first layer 11 and having the first conductivity type and a second exposed surface 28a provided on at least part of the third layer 28 and having the second conductivity type are connected to the interconnection portion 60. In this case, an electrode 57 provided on the first surface 11a and the interconnection portion 60 may be connected. Furthermore, an electrode 59 provided on the second surface 28a and the interconnection portion 60 may be connected. The interconnection portion 60 may be a bonding wire.

The first exposed surface 11a may be made into a bottom surface of a step extending from the second layer 18 side to the part of the first layer 11 by using the RIE method or the like. The second exposed surface 28a may be made into a bottom surface of a step extending from the fourth layer 21 side to the part of the third layer 28 by using the RIE method or the like.

The peak emission wavelength of the light emitted from the first light emitting layer 15 and the peak emission wavelength of the light emitted from the second light emitting layer 25 are set substantially the same.

When the light emitting layers 15 and 25 contain InₓGa_{y}Al_{1-x-y}N (0≦x≦1, 0≦y≦1, x+y≦1), the peak emission wavelength allows, for example, bluish violet to blue light (a wavelength range of 405 to 490 nm) to be emitted upward or sideward. When the first and second semiconductor light emitting elements 30 and 40 are covered with a wavelength conversion layer in which a yellow fluorescent substance is dispersed, a mixed color such as, for example, white color can be emitted.

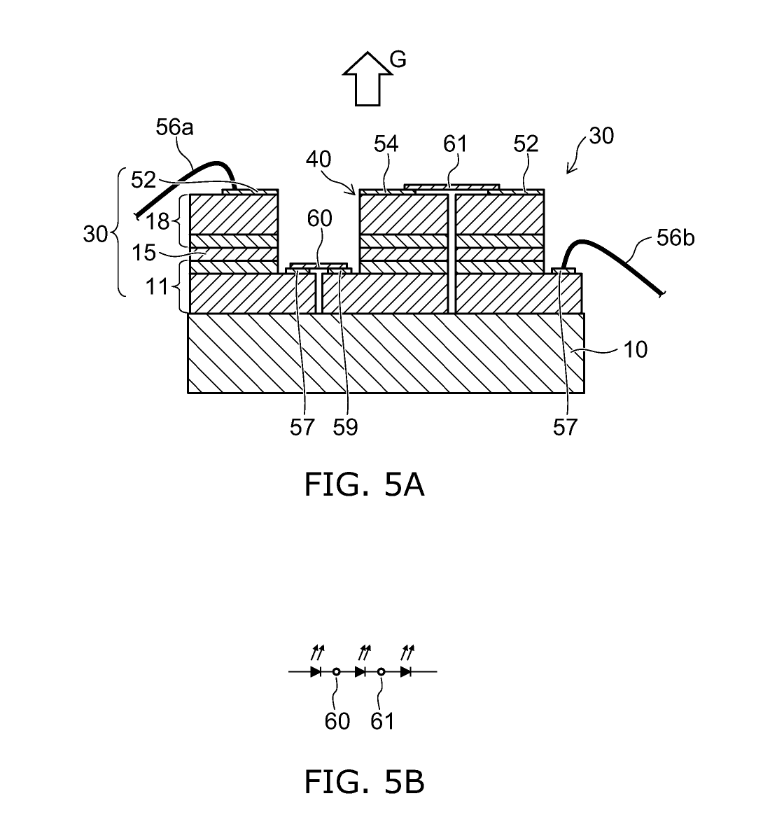

FIG. 5A is a schematic cross-sectional view of a modification example of the second embodiment, and FIG. 5B is a wiring diagram.

In the modification example, three semiconductor light emitting elements are connected in series via interconnection portions 60 and 61. The first electrode 52 and the second electrode 57 provided individually on both sides of the upper surface of the chip may be connected to leads of mounting members using bonding wires 56a and 56b, respectively. Thus, the number of elements connected in series can be freely determined only by altering the dicing position.

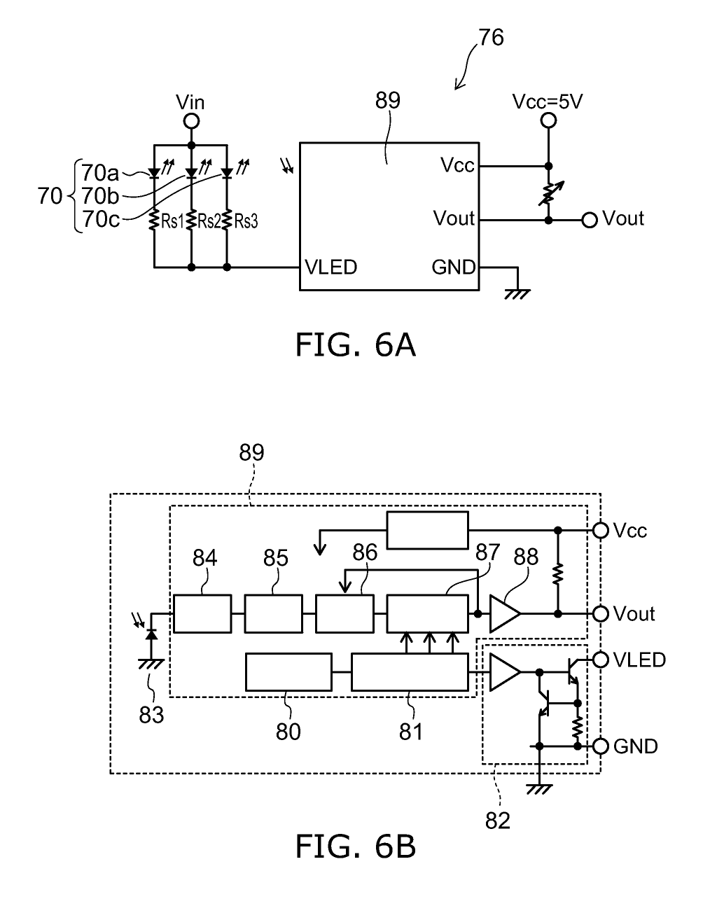

FIG. 6A is a configuration diagram of a lighting apparatus according to a third embodiment, and FIG. 6B is a block diagram showing an abnormality detection circuit for illumination light.

A lighting apparatus 76 has a configuration in which semiconductor light emitting devices 70 are connected in parallel to increase brightness. For example, in the case of automobiles or the like in which the power supply voltage is near 12.5 V, a semiconductor light emitting device like the first or second embodiment in which semiconductor light emitting elements are connected in series may be used. When the output of one of the semiconductor light emitting devices 70 connected in parallel has decreased, the lighting apparatus 76 of the third embodiment detects abnormality, and can enhance the reliability of the lighting system.

The lighting apparatus 76 of the embodiment includes three semiconductor light emitting devices 70a, 70b, and 70c, a pulse drive circuit 82, a light receiving element 83, and a detection circuit 89. The pulse drive circuit 82 pulse-drives the three semiconductor light emitting devices 70a, 70b, and 70c. The light receiving element 83 formed of a photodiode or the like receives part of each of the pulse light outputs emitted from the plurality of semiconductor light emitting devices 70a, 70b, and 70c, as monitor light.

The detection circuit 89 includes a head amplifier 84, an AC amplifier 85, a comparator 86, a signal processing circuit 87, an output circuit 88, an oscillator circuit 80, a timing signal generation circuit 81, etc. That is, the detection circuit 89 inputs a timing signal to the LED pulse drive circuit 82 and the signal processing circuit 87; when the quantity of light received by the light receiving element 83 has become smaller than a prescribed value, the detection circuit 89 outputs an abnormality signal from an output terminal Vout. Of the quantity of light inputted to the light receiving element 83, the component of disturbance light is subtracted. If the semiconductor light emitting device 70 stops emitting light due to disconnection or the like, the output of the comparator 86 is switched, and the output circuit 88 outputs an output decrease signal.

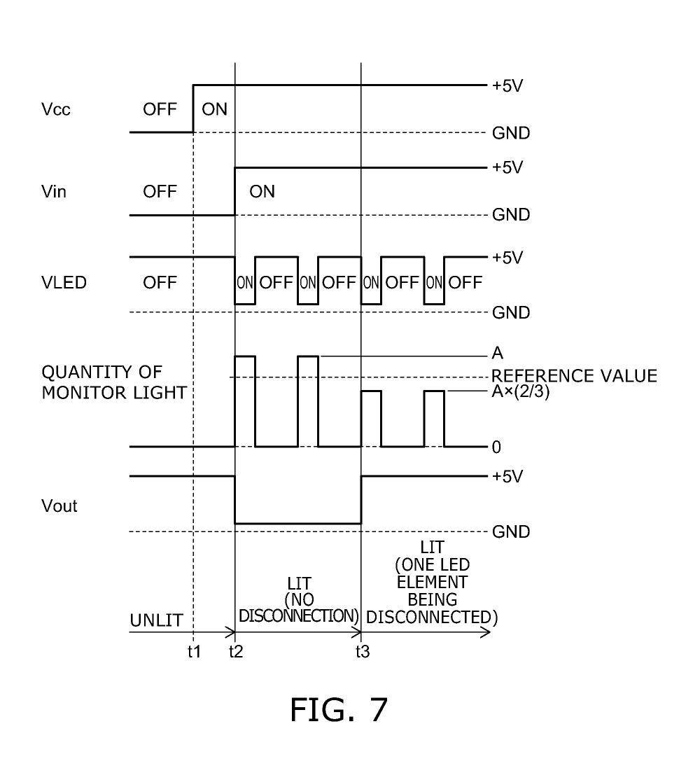

FIG. 7 is a timing chart describing the operation of abnormality detection.

When at time t1, for example, a power supply voltage Vcc of 5 V is switched to ON for the detection circuit 89, the LED pulse drive circuit 82 and the detection circuit 89 become ON, but the semiconductor light emitting device 70 remains in the OFF state. When at time t2, for example, an LED drive voltage Vin of 5 V becomes ON, the pulse drive circuit 82 generates a drive pulse and supplies a voltage VLED to the semiconductor light emitting devices 70a, 70b, and 70c. Although pulse drive is made, the light appears to be continuously lit to a person' eye.

Although the semiconductor light emitting devices 70a, 70b, and 70c emit illumination light, part of the illumination light is monitored with the light receiving element 83. When all of the semiconductor light emitting devices 70a, 70b, and 70c are lit, the quantity of monitor light is like an A level at and after time t2. The reference value of the comparator 86 is, for example, set slightly larger than two thirds of the quantity of monitor light when all the semiconductor light emitting devices are lit. If at time t3 one semiconductor light emitting device experiences disconnection to become unlit, the comparator 86 detects the quantity of monitor light having become smaller than the reference value, and can output an abnormality signal.

Since the light receiving element 83 receives also disturbance light such as that of a fluorescent lamp, the monitor light is susceptible to disturbance light. By pulse-driving the semiconductor light emitting device 70, the component of disturbance light out of the monitor light can be removed and the light quantity change can be detected with good accuracy. The abnormality detection circuit of the embodiment has a simpler configuration than a circuit in which disconnections of a plurality of light emitting elements are individually detected by a photocoupler or a comparator. Therefore, the abnormality detection circuit of the embodiment is easy to downsize.

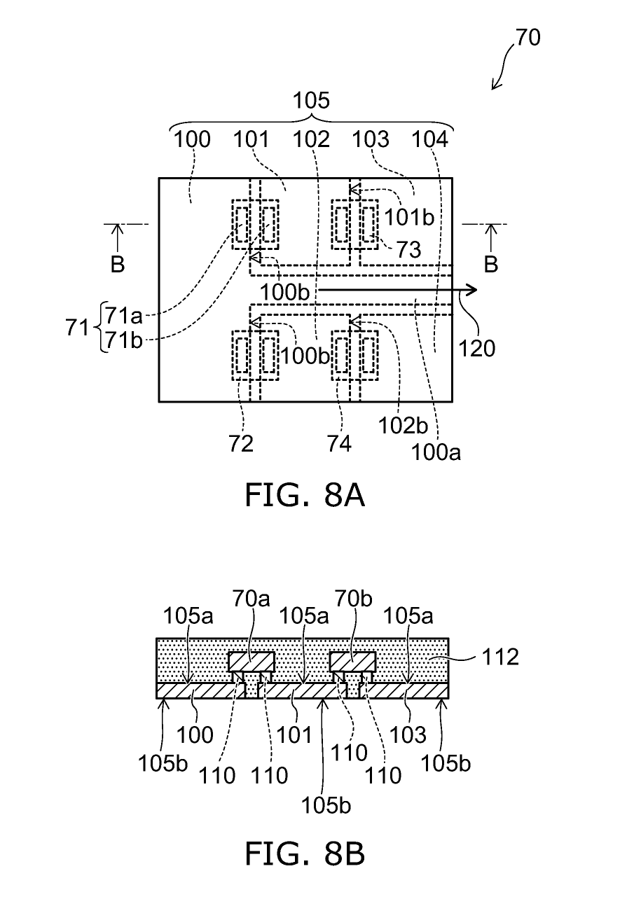

FIG. 8A is a schematic cross-sectional view of a semiconductor light emitting device according to a fourth embodiment, and FIG. 8B is a schematic cross-sectional view taken along line B-B.

The semiconductor light emitting device 70 includes a mounting member made of a metal thin plate and having a mounting surface, a first to a fourth semiconductor light emitting element 71, 72, 73, and 74, and a resin molded body 112. The semiconductor light emitting elements 71, 72, 73, and 74 may be made of Inₓ(Ga_{1-y}Al_{y})₁₋ₓP (0≦x≦1, 0≦y≦1) or InₓGa_{y}Al_{1-x-y}N (0≦x≦1, 0≦y≦1, x+y≦1).

A mounting member 105 includes a first lead 100, a second lead 101, a third lead 102, a fourth lead 103, and a fifth lead 104. The first lead 100 has, as viewed from above, a protrusion 100a extending from near the central portion of a first outer edge 100b along a direction 120 intersecting with the first outer edge 100b. The second lead 101 is provided on one side of the protrusion 100a along the intersecting direction 120 and the first outer edge 100b. The third lead 102 is provided on the other side, which is the opposite side of the one side, of the protrusion 100a along the intersecting direction 120 and the first outer edge 100b. The fourth lead 103 is provided on one side of the intersecting direction 120 of the protrusion 100a along the intersecting direction 120 and the outer edge 101b of the second lead 101. The fifth lead 104 is provided on the other side of the intersecting direction 120 along the intersecting direction 120 and the outer edge 102b of the third lead 102.

That is, the side surface of the second lead 101 has regions opposed to the first outer edge 100b of the first lead 100 and the side surface of the protrusion 100a, with the resin molded body 112 located therebetween. The side surface of the third lead 102 has regions opposed to the first outer edge 100b of the first lead 100 and the side surface of the protrusion 100a, with the resin molded body 112 located therebetween. The side surface of the fourth lead 103 has regions opposed to the outer edge 101b of the second lead 101 and the side surface of the protrusion 100a, with the resin molded body 112 located therebetween. The side surface of the fifth lead 104 has regions opposed to the outer edge 102b of the third lead 102 and the side surface of the protrusion 100a, with the resin molded body 112 located therebetween.

The metal thin plate is made of an iron-based or copper-based alloy or the like, and the thickness thereof is set to 0.15 to 0.4 mm or the like. The mounting member 105 may have a configuration in which a large number of lead frames are connected. When the angle between the first outer edge 100b and the intersecting direction 120 is set to substantially 90 degrees, the symmetry of the directional characteristics of emitted light can be enhanced.

The mounting member 105 has a mounting surface 105a and a back surface 105b on the opposite side of the mounting surface 105a. The first semiconductor light emitting element 71 is, on the mounting surface 105a side of the mounting member 105, electrically connected to the first lead 100 and the second lead 101 using metal bumps 110 or the like. The second semiconductor light emitting element 72 is, on the mounting surface 105a side of the mounting member 105, electrically connected to the first lead 100 and the third lead 102 using the metal bumps 110 or the like. The third semiconductor light emitting element 73 is, on the mounting surface 105a side of the mounting member 105, electrically connected to the second lead 101 and the fourth lead 103 using the metal bumps 110 or the like. The fourth semiconductor light emitting element 74 is, on the mounting surface 105a side of the mounting member 105, electrically connected to the third lead 102 and the fifth lead 104 using the metal bumps 110 or the like. The spacing between adjacent ones of the leads may be, for example, 0.2 to 0.4 mm or the like.

The resin molded body 112 is provided so as to cover the first to fourth semiconductor light emitting elements 71, 72, 73, and 74 and connect the first to fifth leads 100, 101, 102, 103, and 104. When the resin molded body 112 is configured to be provided on the mounting surface 105a side and not be provided on the back surface 105b side, installation on a circuit substrate or the like can be made using bumps, solder members, or the like. The transparent resin molded body 112 is made of, for example, such as an epoxy and a silicone. When the semiconductor light emitting elements 71, 72, 73, and 74 are made of InₓGa_{y}Al_{1-x-y}N (0≦x≦1, 0≦y≦1, x+y≦1), fluorescent particles may be arranged to be dispersed in the resin molded body 112, and a mixed color such as white color can be emitted.

The first lead 100 has the protrusion 100a along the intersecting direction 120. The second to fifth leads 101, 103, 102, and 104 are extended along the intersecting direction 120 and are connected by the resin molded body 112. In this case, the protrusion 100a may have a T-shaped planar configuration; thereby, the bending strength in the intersecting direction 120 can be enhanced. The polarity of the semiconductor light emitting element may be changed; thereby, various connections can be made.

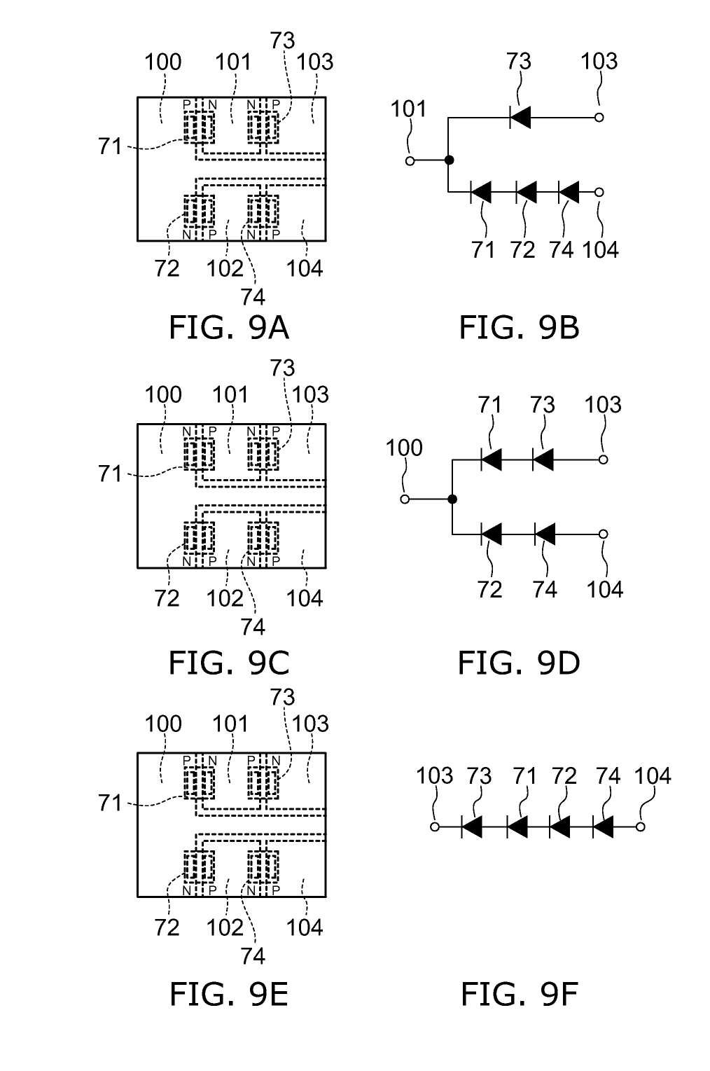

FIG. 9A is a schematic plan view of a first configuration, FIG. 9B is a wiring diagram thereof, FIG. 9C is a schematic plan view of a second configuration, FIG. 9D is a wiring diagram thereof, FIG. 9E is a schematic plan view of a third configuration, and FIG. 9F is a wiring diagram thereof.

FIGS. 9A and 9B show the first configuration in which the second lead 101 is used as a common cathode, and the fourth lead 103 and the fifth lead 104 are used as anodes. FIGS. 9C and 9D show the second configuration in which the first lead 100 is used as a common cathode, and the fourth lead 103 and the fifth lead 104 are used as anodes. FIGS. 9E and 9F show the third configuration in which four elements are connected in series using the fourth lead 103 as a cathode and using the fifth lead 104 as an anode.

The number of semiconductor light emitting elements may be smaller than 4. For example, in the case where the number of semiconductor light emitting elements is two, the fourth and fifth leads may be removed. Alternatively, the fourth and fifth leads 103 and 104 not used may be connected by a bonding wire or the like. Furthermore, semiconductor light emitting elements may be provided in parallel between two leads. In the embodiment, the polarity of the semiconductor light emitting element is changed, and thereby various connections become possible.

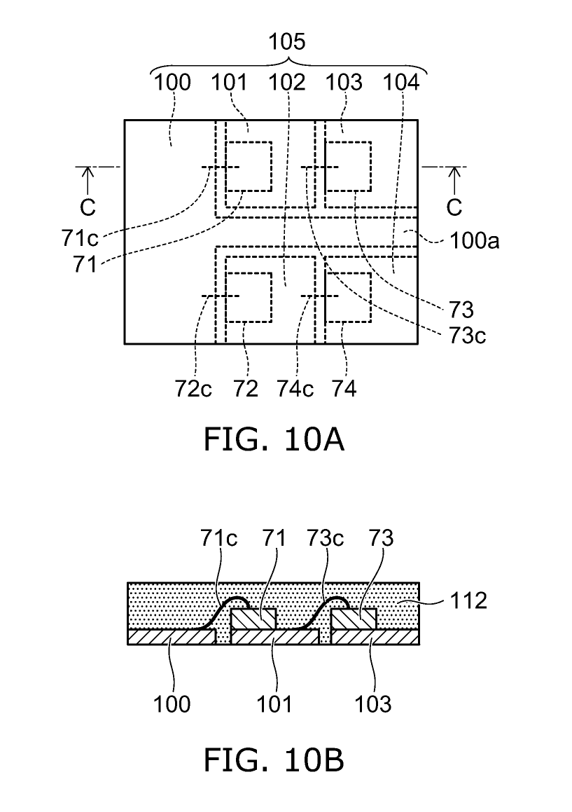

FIG. 10A is a schematic plan view of a semiconductor light emitting device according to a modification example of the fourth embodiment, and FIG. 10B is a schematic cross-sectional view taken along line C-C.

The mounting member 105 and the semiconductor light emitting element may be electrically connected by a bonding wire. In this case, for example, it is assumed that the semiconductor light emitting elements 71, 72, 73, and 74 are vertically conductive. Electrodes provided on the lower surfaces of the semiconductor light emitting elements 71, 72, 73, and 74 and the mounting member 105 are bonded together by a metal solder material or a conductive adhesive. On the other hand, electrodes provided on the upper surfaces of the semiconductor light emitting elements 71, 72, 73, and 74 may be connected to the mounting surfaces 105a of adjacent leads by bonding wires 71c, 72c, 73c, and 74c or the like. The resin molded body 112 is provided so as to cover the bonding wires 71c, 72c, 73c, and 74c.

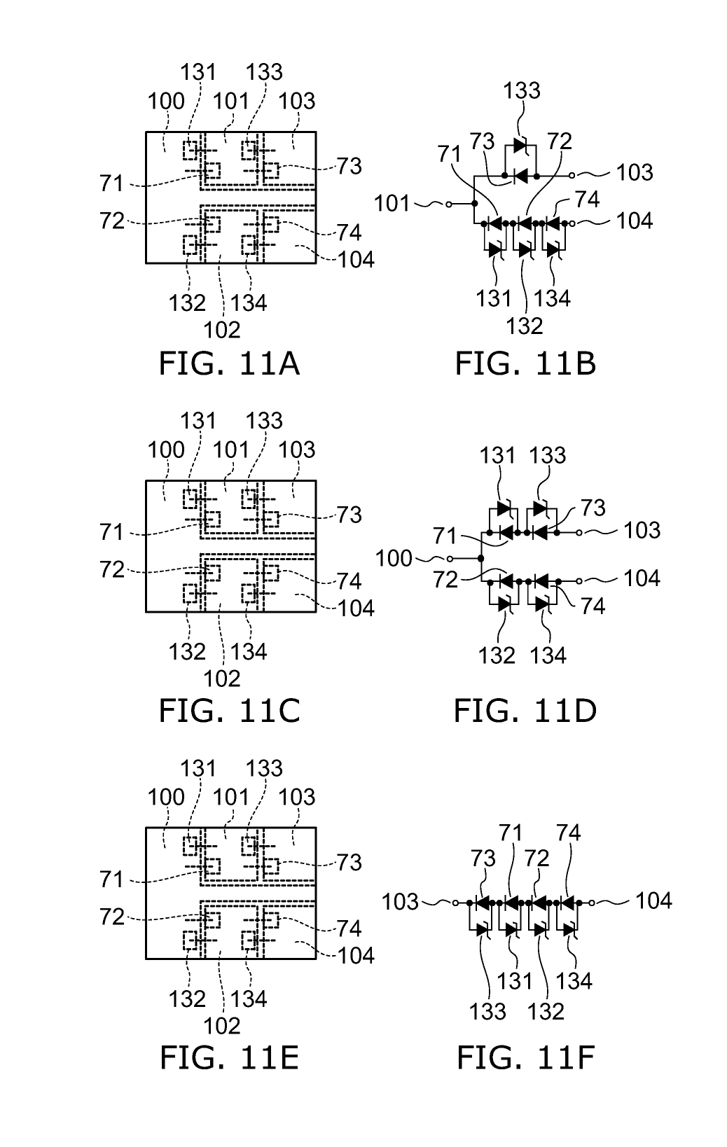

FIG. 11A is a schematic plan view of a first configuration of a semiconductor light emitting device according to a fifth embodiment, FIG. 11B is a wiring diagram thereof, FIG. 11C is a schematic plan view of a second configuration, FIG. 11D is a wiring diagram thereof, FIG. 11E is a schematic plan view of a third configuration, and FIG. 11F is a wiring diagram thereof.

Semiconductor light emitting devices including Zener diodes 131, 132, 133, and 134 connected in the opposite directions to the semiconductor light emitting elements 71, 72, 73, and 74, respectively, can enhance the ESD (electro-static discharge) breakdown voltage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor light emitting device comprising:
a substrate;
a first semiconductor light emitting element provided on the substrate and including a first layer having a first conductivity type, a first light emitting layer provided on the first layer, and a second layer provided on the first light emitting layer and having a second conductivity type; and
a second semiconductor light emitting element provided on the substrate and including a third layer having a second conductivity type, a second light emitting layer provided on the third layer, and a fourth layer provided on the second light emitting layer and having a first conductivity type,
the first layer and the third layer being electrically connected, and
a peak emission wavelength of light emitted from the first light emitting layer and a peak emission wavelength of light emitted from the second light emitting layer being substantially same.

2. The device according to claim 1, wherein the substrate is conductive electrically and connected to the first layer and the third layer.

3. The device according to claim 1, further comprising:
a first interconnection portion electrically connecting the first layer and the third layer,
a first exposed surface provided on at least part of the first layer and having a first conductivity type and a second exposed surface provided on at least part of the third layer and having a second conductivity type being connected to the first interconnection unit.

4. The device according to claim 3, wherein
the first exposed surface is a bottom surface of a step extending from the second layer side to the part of the first layer and
the second surface is a bottom surface of a step extending from the fourth layer side to the part of the third layer.

5. The device according to claim 4, wherein the substrate has insulating properties.

6. The device according to claim 5, further comprising:
a third semiconductor light emitting element provided on the substrate and including a fifth layer having a second conductivity type, a third light emitting layer provided on the fifth layer, and a sixth layer provided on the third light emitting layer and having a first conductivity type; and
a second interconnection portion electrically connecting a surface of the fourth layer and a surface of the sixth layer,
a peak emission wavelength of light emitted from the first light emitting layer, a peak emission wavelength of light emitted from the second light emitting layer, and a peak emission wavelength of light emitted from the third light emitting layer being substantially same.

7. The device according to claim 1, wherein both of the first light emitting layer and the second light emitting layer contain Inₓ(Ga_{1-y}Al_{y})₁₋ₓP (0≦x≦1, 0≦y≦1) or contain InₓGa_{y}Al_{1-x-y}N (0≦x≦1, 0≦y≦1, x+y≦1).

8. A semiconductor light emitting device comprising:
a mounting member including a metal thin plate including a first lead having a protrusion extending from a central portion of a first outer edge in a direction intersecting with the first outer edge, a second lead provided on one side of the protrusion along the intersecting direction and the first outer edge, and a third lead provided on another side of the protrusion on an opposite side of the one side along the intersecting direction and the first outer edge, the mounting member having a mounting surface and a back surface on an opposite side of the mounting surface;
a first semiconductor light emitting element electrically connected to the first lead and the second lead and provided on the mounting surface side;
a second semiconductor light emitting element electrically connected to the first lead and the third lead and provided on the mounting surface side; and
a resin molded body covering the first and second semiconductor light emitting elements, connecting the first to third leads, and being transparent,
the resin molded body covering the mounting surface but not covering the back surface.

9. The device according to claim 8, wherein an angle between the first outer edge of the first lead and the intersecting direction is substantially 90 degrees.

10. The device according to claim 9, further comprising:
a third and a fourth semiconductor light emitting element provided on the mounting surface side of the mounting member,
the metal thin plate of the mounting member further including a fourth lead provided on the one side of the protrusion along the intersecting direction and an outer edge of the second lead and a fifth lead provided on the other side of the protrusion along the intersecting direction and an outer edge of the third lead,
the third semiconductor light emitting element being electrically connected to the second lead and the fourth lead,
the fourth semiconductor light emitting element being electrically connected to the third lead and the fifth lead, and
the resin molded body further covering the third and fourth semiconductor light emitting elements and further connecting the fourth and fifth leads.

11. The device according to claim 10, wherein the second, third, fourth, and fifth leads are rectangular shapes having same size.

12. The device according to claim 10, wherein the first to fourth light emitting elements and the mounting surface are electrically connected by bumps or bonding wires.

13. The device according to claim 10, further comprising Zener diodes connected in antiparallel to the first to fourth light emitting elements, respectively.

14. The device according to claim 10, wherein a voltage having a first polarity is supplied to the second lead and a voltage having a second polarity opposite to the first polarity is supplied to the fourth lead and the fifth lead.

15. The device according to claim 10, wherein a voltage of a first polarity is supplied to the first lead and a voltage of a second polarity opposite to the first polarity is supplied to the fourth lead and the fifth lead.

16. The device according to claim 10, wherein a voltage having a first polarity is supplied to the fourth lead and a voltage of a second polarity opposite to the first polarity is supplied to the fifth lead.

17. The device according to claim 8, wherein both of the first light emitting layer and the second light emitting layer contain Inₓ(Ga_{1-y}Al_{y})₁₋ₓP (0≦x≦1, 0≦y≦1) or contain InₓGa_{y}Al_{1-x-y}N (0≦x≦1, 0≦y≦1, x+y≦1).

18. A lighting apparatus comprising:
a plurality of semiconductor light emitting devices connected in parallel;
a pulse drive circuit configured to pulse-drive the plurality of semiconductor light emitting devices;
a light receiving element configured to receive part of each of pulse light outputs emitted from the plurality of semiconductor light emitting devices; and
a detection circuit configured to output an output decrease signal when a quantity of light received by the light receiving element has become smaller than a prescribed value.

19. The apparatus according to claim 18, wherein the semiconductor light emitting device includes a light emitting layer made of Inₓ(Ga_{1-y}Al_{y})₁₋ₓP (0≦x≦1, 0≦y≦0.6) and emits red light.

20. The apparatus according to claim 18, wherein the detection circuit includes an amplifier to which a monitor current from the light receiving element is inputted, a comparator that compares an intensity of the pulse light output to a reference value, a signal processing circuit, and a timing signal generating circuit that inputs a timing signal to the pulse drive circuit and the signal processing circuit.
